(19) United States
(12) Patent Application Publication
(10) Pub. No.: US 2025/0349651 A1
(43) Pub. Date: Nov. 13, 2025

(54) INTEGRATED CIRCUIT (IC) STRUCTURES WITH THERMAL VIAS AND HEAT SPREADER LAYERS

(71) Applicant: Taiwan Semiconductor Manufacturing Company, Ltd., Hsin-Chu (TW)

(72) Inventors: Isha Datye, Hsinchu (TW); Sam Vaziri, San Jose, CA (US); Xinyu Bao, Fremont, CA (US)

(21) Appl. No.: 19/278,387

(22) Filed: Jul. 23, 2025

Related U.S. Application Data
(63) Continuation of application No. 18/588,069, filed on Feb. 27, 2024.
(60) Provisional application No. 63/595,010, filed on Nov. 1, 2023.

(51) Int. Cl. H01L 23/367; H01L 21/768; H01L 23/00; H01L 23/373; H01L 23/48; H01L 25/065; H10D 84/01; H10D 84/03; H10D 84/83

(52) U.S. Cl. CPC H01L 23/367; H01L 21/76898; H01L 23/3732; H01L 23/481; H01L 24/05; H01L 25/0657; H10D 84/0149; H10D 84/038; H10D 84/83; H01L 2224/05624; H01L 2225/06541; H01L 2924/13091

(57) ABSTRACT

An IC structure includes a frontside interconnect structure on a front side of a device layer, the frontside interconnect structure includes first metal features and second metal features isolated from each other by and embedded in an IMD layer, the first metal features are electrically connected to the transistor devices, and the second metal features are electrically isolated from the transistor devices; a backside interconnect structure on a back side of the device layer, the backside interconnect structure includes third metal features and fourth metal features isolated from each other by and embedded in a backside IMD layer, the third metal features are electrically connected to the transistor devices, and the fourth metal features are electrically isolated from the transistor devices. The IC structure further includes a heat spreader layer having a material that is thermally conductive and electrically insulating on a back side of the backside interconnect structure.

### PRIORITY DATA

This application is a continuation application of U.S. patent application Ser. No. 18,588,069, filed Feb. 27, 2024, which claims the benefit of U.S. Provisional Application No. 63/595,010 filed Nov. 1, 2023, each of which is herein incorporated by reference in its entirety.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

As technology nodes become smaller, signal and power connections may be routed to a backside of a circuit structure for power and chip space optimization. In these cases, after forming frontside IC features, the device substrate of the circuit structure is thinned down from a backside to prepare for forming backside IC features. The device substrate may be partially or fully removed. However, removing the device substrate causes the IC circuit to have poorer thermal dissipation, which could lead to higher temperatures that degrade device performance. The device substrate previously provided a thermal path to absorb heat generated from the transistor devices. With a thinned-down device substrate, more heat may be trapped in the device areas, creating hot spots that may cause device breakdown due to self-heating.

Therefore, although existing IC structures having backside features for signal and power connections have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates a cross-sectional view of an integrated circuit (IC) structure having thermal vias and a heat spreader layer, according to an embodiment of the present disclosure.

FIG. 2A illustrates a cross-sectional view of an IC structure having floating thermal vias, according to an embodiment of the present disclosure.

FIG. 2B illustrates a cross-sectional view of an IC structure having floating and non-floating thermal vias, according to an embodiment of the present disclosure.

FIG. 3A illustrates a cross-sectional view of an IC structure having floating thermal vias and a heat spreader layer, according to an embodiment of the present disclosure.

FIG. 3B illustrates a cross-sectional view of an IC structure having floating thermal vias and a heat spreader layer, according to another embodiment of the present disclosure.

FIG. 4A illustrates a cross-sectional view of an IC structure having floating and non-floating thermal vias and a heat spreader layer, according to an embodiment of the present disclosure.

FIG. 4B illustrates a cross-sectional view of an IC structure having floating and non-floating thermal vias and a heat spreader layer, according to another embodiment of the present disclosure.

FIG. 5 illustrates a top view of an IC chip having a circuit region, the circuit region having thermal vias of different shapes and size configurations, according to an embodiment of the present disclosure.

FIGS. 6A, 7A, and 8A illustrate top views of a frontside interconnect structure in a circuit region of an IC chip, according to various embodiments of the present disclosure.

FIGS. 6B, 7B, and 8B illustrate top views of a backside interconnect structure in a circuit region of an IC chip, according to various embodiments of the present disclosure.

FIG. 9 illustrates a flow chart of a method to form an IC structure having thermal vias and a heat spreader layer, according to an embodiment of the present disclosure.

FIGS. 10, 11, 12, 13, and 14 illustrate the formation of an IC structure having thermal vias and a heat spreader layer at intermediate stages of fabrication, processed in accordance with the method of FIG. 9, according to an embodiment of the present disclosure.

FIGS. 15A, 15B, and 15C illustrate graphs showing thermal improvements that can be achieved through heat spreaders and thermal vias.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +1-15% by one of ordinary skill in the art. Further, disclosed dimensions of the different features can implicitly disclose dimension ratios between the different features. Still further, the present disclosure may repeat reference numerals and/or letters in the various examples. This repetition is for the purpose of simplicity and clarity and does not in itself dictate a relationship between the various embodiments and/or configurations discussed.

The present disclosure relates to integrated circuit (IC) structures with backside power delivery networks, and particularly to incorporating thermal vias and heat spreader layers to reduce power consumption and to improve power distribution. As opposed to IC structures having only frontside power delivery networks, IC structures with backside power delivery networks reduce voltage drop from the many metals in the frontside metal interconnects, thereby improving power delivery performance, and allowing for further standard cell height scaling. However, forming backside power delivery networks requires thinning down the original device substrate (e.g., to accommodate through-vias (TSVs)), which leads to higher temperatures that degrade device performance. The present disclosure describes various solutions to lower temperature and to reduce device hotspots in IC structures that have backside power delivery networks.

In various embodiment, the present disclosure describes an IC structure (or IC chip) with backside IC features formed on a backside of a transistor device layer. The backside IC features form a backside power delivery network for delivering power signals from a backside of the IC chip. The backside power delivery network reduces power dissipation and routing congesting in the frontside metal layers. The IC structure includes a heat spreader layer (e.g., having diamond) and thermal vias (e.g., having copper or diamond) to effectively dissipate heat and to reduce the hot spot temperature in the logic layer. The heat spreader layer and thermal vias can be integrated in different parts of the IC structure, depending on the process requirements, and to target hot spot regions of the IC structure. The heat spreader layer and thermal vias can be grown directly on the chip at low temperatures (less than 400 degrees Celsius) to be compatible with back end of line (BEOL) processes. This means that the heat spreader layer and thermal vias need not withstand high temperature stress (greater than 900 degrees Celsius) during front end of line (FEOL) processes. In other words, the heat spreader layer and thermal vias may be formed as part of one or more BEOL processes, thus the high temperature stress during FEOL processes will not affect the formation of the heat spreader layer and thermal vias. As such, there is more freedom in choosing the thermal materials used for the heat spreader layer and thermal vias. Further, since the heat spreader layer and thermal vias are formed at low temperatures, it will not affect previously formed BEOL structures. FEOL generally refers to portions of the circuit where functional devices such as logic and memory devices are formed. The FEOL generally includes everything up to but not including metal interconnect layers. These regions may include the substrate, source/drain features, channel regions, gate, and device-level metal features (e.g., device-level contacts and vias). BEOL generally refers to circuit regions outside of the FEOL. These regions may include the metal interconnect layers, backside of the substrate, or another wafer as part of a 3DIC structure.

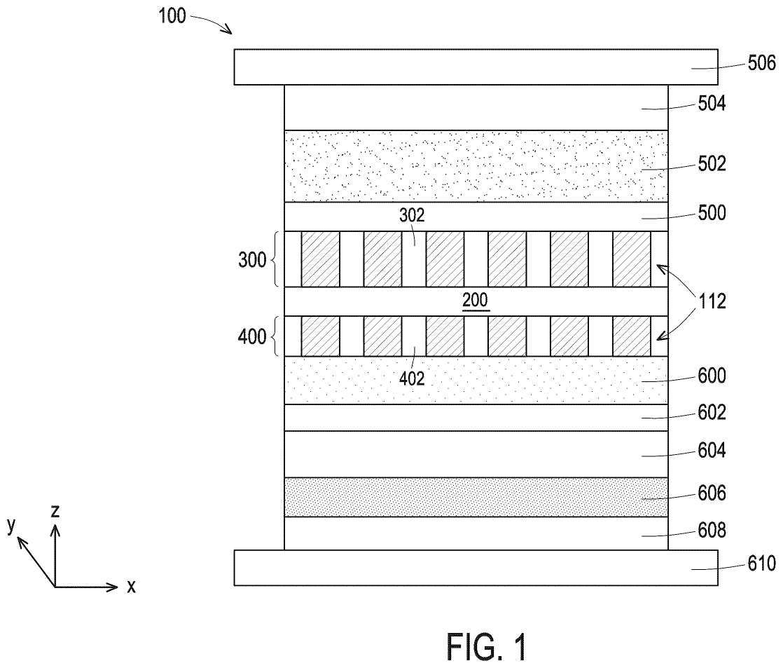

FIG. 1 illustrates a cross-sectional view of an integrated circuit (IC) structure 100, according to an embodiment of the present disclosure. The IC structure 100 may be an IC package mounted onto a printed circuit board (PCB). As shown, the IC structure 100 includes a device layer 200 sandwiched between various IC layers and components. The device layer 200 is where device-level features such as transistor devices are formed. The transistor devices may be logic devices, memory devices, or the like. Each of the transistor devices includes a channel region between source/drain (S/D) regions and a gate stack over the channel regions. The device layer 200 may further include other device-level features such as S/D contacts, S/D vias, gate contacts, and/or gate vias, each of which may electrically connect the S/D regions and/or the gate stacks to a higher material layer of the IC structure 100. In an embodiment, the device layer 200 has a thickness between about 0.05 μm to about 0.5 μm. In an embodiment, the device layer 200 has a thermal conductivity kₓ/k_{y} in the x and y direction of between about 10 W/m/K to about 100 W/m/K, and a thermal conductivity k_{z} in the z direction of between about 10 W/m/K to about 100 W/m/K.

Still referring to FIG. 1, on a front side of the device layer 200, the IC structure 100 includes a frontside interconnect structure 300 over the device layer 200, a bonding layer 500 over the frontside interconnect structure 300, a carrier substrate 502 over the bonding layer 500, a thermal interface material (TIM) layer 504 over the carrier substrate 502, and a top lid 506 over the TIM layer 504.

The frontside interconnect structure 300 includes one or more thermal vias 112 embedded within a frontside intermetal dielectric (IMD) layer 302. As shown, the thermal vias 112 may vertically span the entire height of the frontside interconnect structure 300, having one end directly contacting the device layer 200 and the opposite end directly contacting the bonding layer 500. The thermal vias 112 do not electrically connect to any of the transistor devices in the device layer 200. Instead, they act as heat spreading features embedded in the frontside IMD layer 302. To that effect, they function to capture and to transfer heat away from hot spots. The frontside IMD layer 302 may include silicon oxide, silicon oxynitride, fluorine-doped silicate glass (FSG), a low-k dielectric, combinations thereof, and/or other suitable dielectric materials. In an embodiment, the frontside interconnect structure 300 has a thickness between about 0.5 μm to about 2 μm. In an embodiment, the frontside interconnect structure 300 has a thermal conductivity kₓ/k_{y} in the x and y direction of between about 1 W/m/K to about 15 W/m/K, and a thermal conductivity k_{z} in the z direction of between about 0.1 W/m/K to about 1 W/m/K.

The bonding layer 500 may be a metal bonding layer, an oxide bonding layer, or a bonding layer having a hybrid of metal and oxide. In any case, the bonding layer 500 glues a top surface of the frontside interconnect structure 300 to the carrier substrate 502. In an embodiment, the bonding layer 500 has a thickness between about 0.1 μm to about 0.5 μm. In an embodiment, the bonding layer 500 has a thermal conductivity kₓ/k_{y} in the x and y direction of between about 0.5 W/m/K to about 2 W/m/K, and a thermal conductivity k_{z} in the z direction of between about 0.5 W/m/K to about 5 W/m/K.

The carrier substrate 502 provides structural support in preparation for backside processing. The carrier substrate 502 may include silicon (Si), or other semiconductor materials such as germanium (Ge), silicon carbide (SiC), silicon germanium (SiGe), or diamond. In the present embodiment, the carrier substrate 502 is made of silicon. In an embodiment, carrier substrate 502 has a thickness between about 350 μm to about 450 μm and exhibits a thermal conductivity k of between about 100 W/m/K to about 150 W/m/K. Note that in the present embodiment, the carrier substrate 502 remains in the IC structure 100 even after backside processing. The carrier substrate 502 is kept for structural support purposes, and also acts as a heat spreader. The TIM layer 504 and the top lid 506 are then formed over the carrier substrate 502.

The TIM layer 504 is disposed over the carrier substrate 502 and may act as a heat conductor and heat distributor on a front side of the workpiece to more uniformly direct heat away from the IC structure 100 (e.g., via the top lid 506). The TIM layer 504 may also act as a protective film to keep out moisture from outside the IC structure 100. The TIM layer 504 may include a polymer, resin, or epoxy as a base material, and a filler to improve its thermal conductivity. The filler may include a dielectric filler such as aluminum oxide, magnesium oxide, aluminum nitride, boron nitride, and diamond powder. Alternatively, the filler may include a metal filler such as silver, copper, aluminum, or the like. In an embodiment, the TIM layer 504 has a thickness between about 50 μm to about 100 μm. In an embodiment, the TIM layer 504 has a thermal conductivity kₓ/k_{y} in the x and y direction of between about 1 W/m/K to about 10 W/m/K, and a thermal conductivity k_{z} in the z direction of between about 1 W/m/K to about 10 W/m/K.

The top lid 506 is disposed over the TIM layer 504. The top lid 506 may be a metal cap that acts as a cover for the IC structure 100. In an embodiment, the top lid 506 not only covers a top surface of the IC workpiece, but also cover side surfaces of the IC workpiece. Besides acting as a cover, the top lid 506 also acts as a heat absorber to absorb any heat dissipated from components of the IC structure 100. The top lid 506 is formed of a metal or a metal alloy, which has a high thermal conductivity, for example, higher than about 100 W/m/K. For example, the top lid 506 may be formed of a metal or a metal alloy selected from Al, Cu, Ni, Co, stainless steel, and alloys thereof. In an embodiment, top lid 506 has a thickness between about 450 μm to about 550 μm and exhibits a thermal conductivity k of between about 350 W/m/K to about 400 W/m/K.

Still referring to FIG. 1, on a back side of the device layer 200, the IC structure 100 includes a backside interconnect structure 400 under the device layer 200, a heat spreader layer 600 under the backside interconnect structure 400, an aluminum bond pad (AP) layer 602 under the heat spreader layer 600, a controlled collapse chip connection (C4) layer 604 under the AP layer 602, a package substrate 606 under the C4 layer 604, a ball-grid array (BGA) structure 608 under the package substrate 606, and a printed circuit board (PCB) 610 under the BGA structure 608.

The backside interconnect structure 400 includes one or more thermal vias 112 embedded within a backside IMD layer 402. As shown, the thermal vias 112 may vertically span the entire height of the backside interconnect structure 400, having one end directly contacting a back side of the device layer 200 and the opposite end directly contacting a top surface of the heat spreader layer 600. The thermal vias 112 do not electrically connect to any of the transistor devices in the device layer 200. Instead, they act as heat absorbing features embedded in the backside IMD layer 402. The backside IMD layer 402 may include silicon oxide, silicon oxynitride, fluorine-doped silicate glass (FSG), a low-k dielectric, combinations thereof, and/or other suitable dielectric materials. In an embodiment, the backside interconnect structure 400 has a thickness between about 1 μm to about 2 μm. In an embodiment, the backside interconnect structure 400 has a thermal conductivity kₓ/k_{y} in the x and y direction of between about 1 W/m/K to about 15 W/m/K, and a thermal conductivity k_{z} in the z direction of between about 10 W/m/K to about 20 W/m/K.

Although FIG. 1 shows thermal vias 112 in both the frontside and backside IMD layers 302 and 402, the present disclosure is not limited thereto. For example, the thermal vias 112 may only be in the frontside IMD layer 302 or only in the backside IMD layer 402 depending on design considerations.

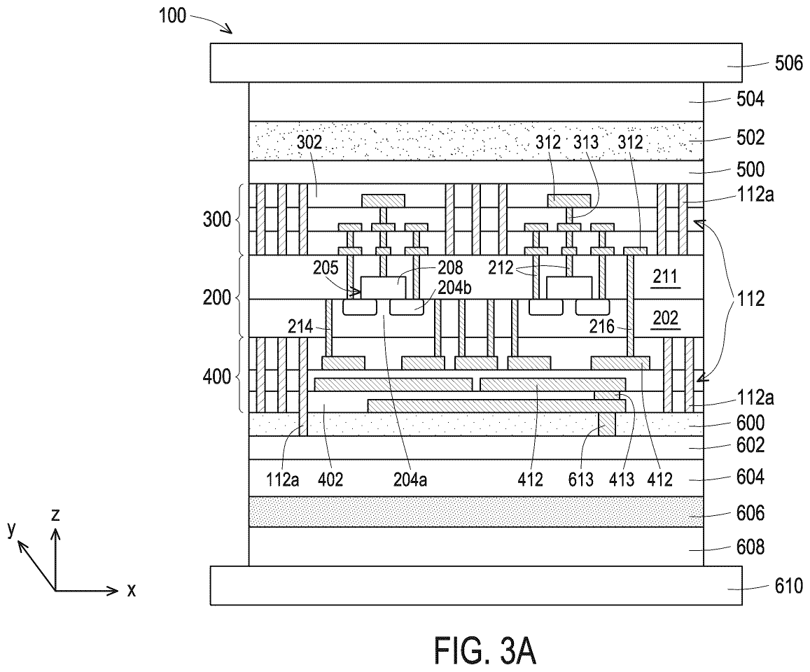

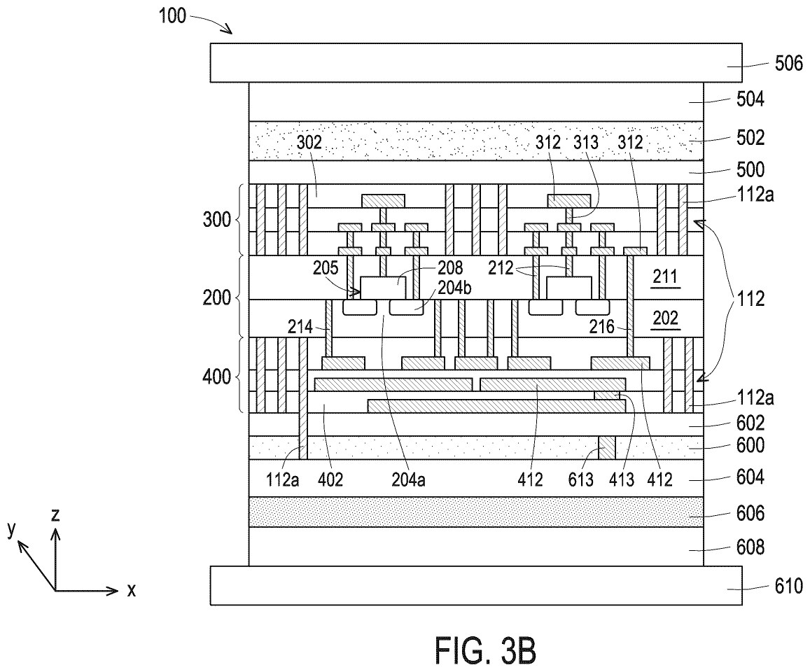

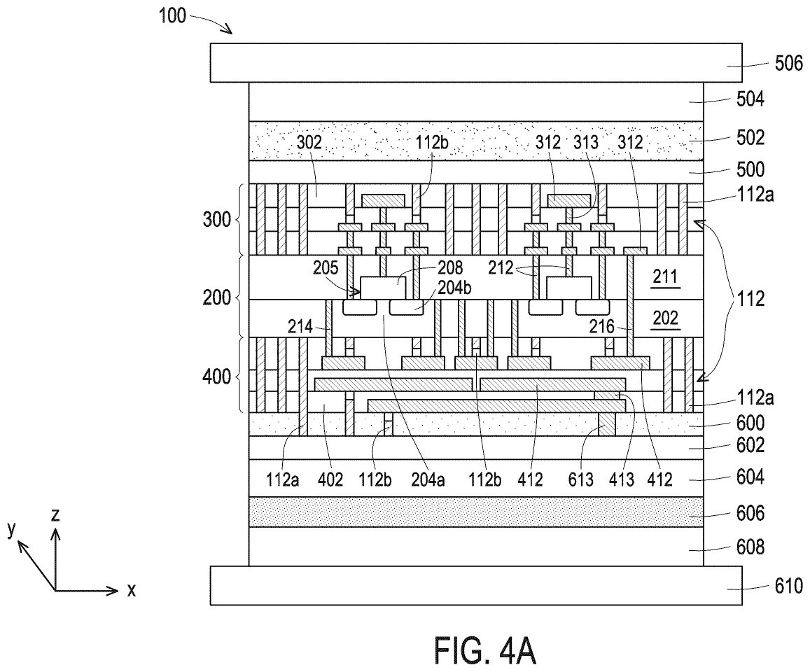

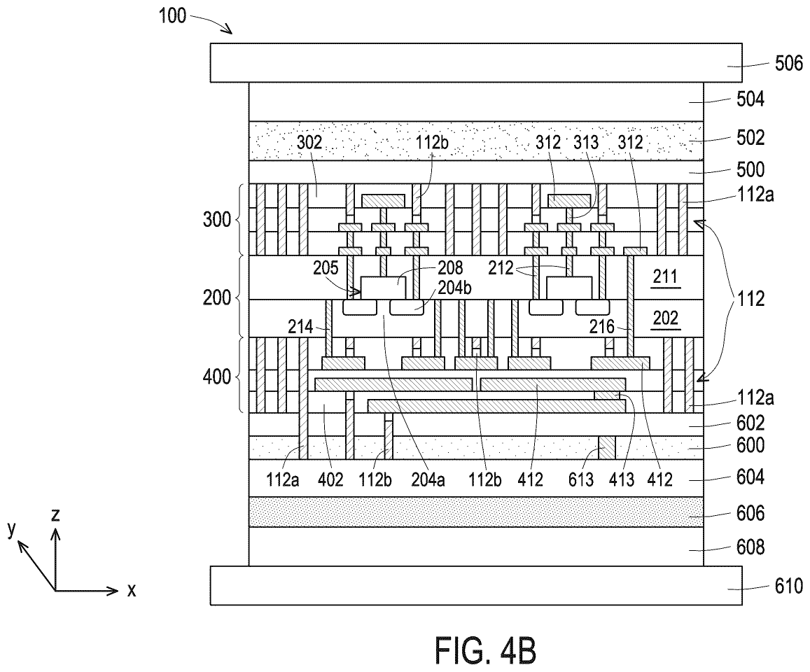

The heat spreader layer 600 is disposed on a back side of the device layer 200. In the embodiment of FIG. 1, the heat spreader layer 600 is disposed between the backside interconnect structure 400 and the AP layer 602, however, the heat spreader layer 600 may alternatively be disposed between the AP layer 602 and the C4 layer 604 (see e.g., FIGS. 3B and 4B). In other words, the heat spreader layer 600 may be disposed immediately below the backside interconnect structure 400 or immediately below the AP layer 602, depending on process requirements. The heat spreader layer can span the whole size of an IC chip, or it can be localized to certain parts of the chip. The heat spreader layer 600 is made of a heat spreader material that is thermally conductive and electrically insulating. The thermal conductivity k for the heat spreader materials should be between about 10 and 500 W/m/K for absorbing heat dissipation. The electrical resistivity ρ of the heat spreader materials should be greater than 10⁸ Ωm for isolating electrical signals (e.g., between 10¹⁰ Ωm and 10¹⁶ Ωm). For example, the heat spreader layer 600 may include materials such as diamond, AlN, BN, Al₂O₃, BeO, or a combination thereof. In an embodiment, the heat spreader layer has a thickness between about 0.1 μm to about 50 μm.

The AP layer 602 is disposed on a back side of the heat spreader layer 600 (or alternatively on a back side of the backside interconnect structure 400). The AP layer 602 includes aluminum bonding pads that electrically connect to electrical metal lines of the backside interconnect structure 400. The aluminum bonding pads may be contact areas of a chip/die configured to connect to other chips/dies. The AP layer 602 may be part of a redistribution layer (RDL) structure. The RDL structure may include redistribution routing lines embedded in one or more passivation layers. The redistribution routing lines may route the metal lines of the backside interconnect structure 400 to the aluminum bonding pads of the AP layer 602. In an embodiment, the AP layer 602 has a thickness between about 2 μm to about 3.5 μm. In an embodiment, the AP layer 602 has a thermal conductivity kₓ/k_{y} in the x and y direction of between about 10 W/m/K to about 20 W/m/K, and a thermal conductivity k_{z} in the z direction of between about 100 W/m/K to about 150 W/m/K.

The C4 layer 604 is disposed on a back side of the AP layer 602 (or alternatively on a back side of the heat spreader layer 600). The C4 layer 604 includes interconnect bumps such as solder bumps or copper pillar (CuP) bumps. The solder bumps may include tin, lead, and/or silver, and the CuP bumps may include a copper pillar having a solder cap at the end. The solder cap may be made of tin, lead, and/or silver. The interconnect bumps act as means for connecting a chip/die to another chip/die as part of an IC package. The interconnect bumps lands on the aluminum bonding pads of the AP layer 602. In an embodiment, the C4 layer 604 has a thickness between about 40 μm to about 80 μm. In an embodiment, the C4 layer 604 has a thermal conductivity kₓ/k_{y} in the x and y direction of between about 1 W/m/K to about 5 W/m/K, and a thermal conductivity k_{z} in the z direction of between about 5 W/m/K to about 10 W/m/K.

The package substrate 606 is disposed on a back side of the C4 layer 604. The package substrate 606 generally refers to a wafer or semiconductor structure that includes package components such as other device chips, silicon interposers, dielectric substrates, and the like. The package components are electrically connected to the aluminum pads in the AP layer 602 through the interconnect bumps of the C4 layer 604. In an embodiment, the package substrate 606 includes a semiconductor substrate formed of silicon, silicon germanium, silicon carbon, or the like. In an embodiment, the package substrate 606 has a thickness between about 250 μm to about 350 μm. In an embodiment, the package substrate 606 has a thermal conductivity kₓ/k_{y} in the x and y direction of between about 10 W/m/K to about 50 W/m/K, and a thermal conductivity k_{z} in the z direction of between about 0.5 W/m/K to about 2 W/m/K.

The BGA structure 608 is disposed on a back side of the package substrate 606. The BGA structure 608 includes solder joints attached to the backside of the package substrate 606. The BGA structure 608 is configured to bond IC packages onto a larger circuit board. In an embodiment, the BGA structure 608 has a thickness between about 100 μm to about 200 μm. In an embodiment, BGA structure 608 has a thermal conductivity kₓ/k_{y} in the x and y direction of between about 0.1 W/m/K to about 1 W/m/K, and a thermal conductivity k_{z} in the z direction of between about 50 W/m/K to about 100 W/m/K.

The printed circuit board (PCB) 610 is disposed on a backside of the BGA structure 608. The PCB 610 may include multiple other IC packages mounted thereon, thereby forming a processor, a controller, a memory unit, or other electronic components. In an embodiment, the PCB 610 has a thickness between about 900 μm to about 1100 μm. In an embodiment, PCB 610 has a thermal conductivity kₓ/k_{y} in the x and y direction of between about 10 W/m/K to about 100 W/m/K, and a thermal conductivity k_{z} in the z direction of between about 1 W/m/K to about 5 W/m/K.

Still referring to FIG. 1, the thermal vias 112 can vary in width (from about 100 nm to 10 μm) and thickness, depending on the density of the metal features in the frontside/backside interconnect structures 300 and 400. The thermal vias 112 may be uniformly or nonuniformly distributed throughout the IC structure 100 and penetrate through one or more of the metal layers of the frontside/backside interconnect structures 300 and 400. The size of the thermal vias 112 can vary from nm to μm depending on the density of metal interconnects (e.g., metal lines) in the frontside and backside interconnect structures 300 and 400. In some embodiments, the thermal vias 112 in the frontside/backside interconnect structures 300 and 400 have greater widths than the electrical vias that route circuit signals in the frontside/backside interconnect structures 300 and 400.

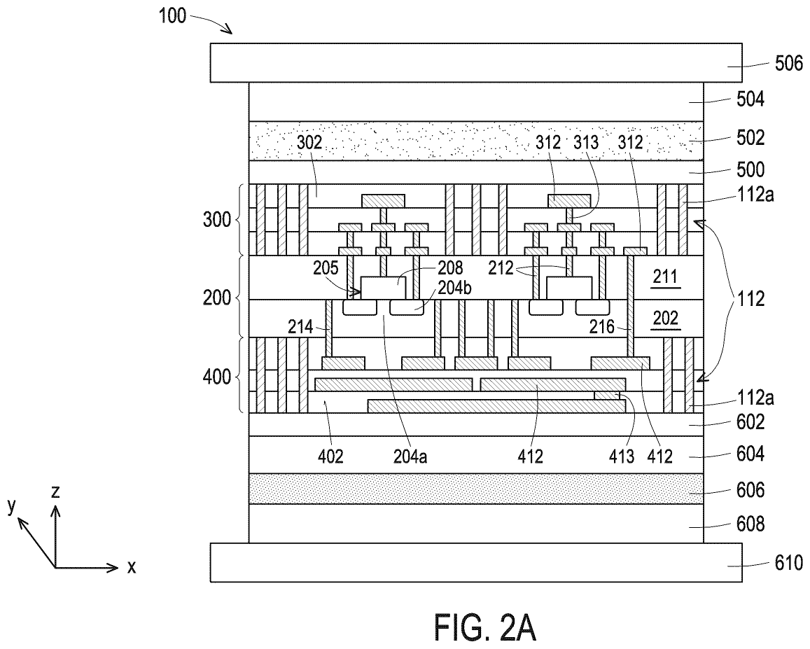

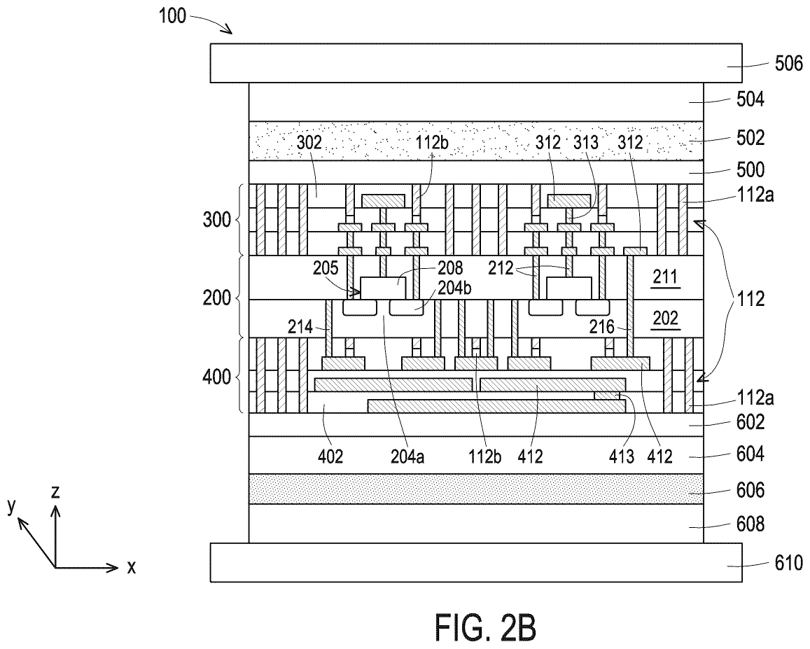

FIG. 2A illustrates a cross-sectional view of an IC structure 100 having thermal vias 112, and particularly floating thermal vias 112a, according to an embodiment of the present disclosure. The IC structure 100 in FIG. 2A is similar to the IC structure 100 in FIG. 1, and the similar features will not be described again for the sake of brevity. The difference is that there is no heat spreader layer 600, and that additional details are shown with respect to the device layer 200, the frontside interconnect structure 300, and the backside interconnect structure 400.

As shown in FIG. 2A, the device layer 200 includes transistor devices 205. Each of the transistor devices 205 includes a channel region 204a between S/D regions 204b, and a gate stack 208 disposed over the channel region 204a. The transistor devices 205 may be planar MOSFETs, FinFETs, or gate-all-around FETs. In an embodiment, the channel regions 204a and S/D regions 204b are formed in an active region over or as part of a device substrate 202. The device substrate 202 may include silicon (Si), or other semiconductor materials such as germanium (Ge), silicon carbide (SiC), silicon germanium (SiGe), or diamond. In the present embodiment, the device substrate 202 is made of silicon. As described later, the device substrate 202 may be partially or full removed as part of forming backside IC features. An interlayer dielectric (ILD) layer 211 is disposed over the device substrate 202 and embeds device-level metal features 212 such as S/D contacts landing on the S/D regions 204b and S/D vias landing on the S/D contacts, and gate contacts landing on the gate stacks 208 and gate vias landing on the gate contacts. The ILD layer 211 may include similar materials as the frontside and backside IMD layers 302 and 402. The device layer 200 may further include buried rails 214 extending below the ILD layer 211 and penetrating through the device substrate 202 to land on a backside electrical metal line 412 in the backside interconnect structure 400. The buried rails 214 may electrically connect to the S/D regions 204b and/or the gate stacks 208 of the transistor devices 205. In an embodiment, the buried rails 214 may route to a front-side power delivery network (e.g., to electrical metal lines 312) through the device layer 200, which then connect to the S/D regions 204b and/or the gate stacks 208 from the frontside. In another embodiment, although not shown, the buried rails 214 may act as backside vias that directly contact S/D regions 204b of the transistor devices 205 from a backside, and the backside vias land on backside electrical metal lines 412 in the backside interconnect structure 400.

Still referring to FIG. 2A, the frontside interconnect structure 300 includes electrical metal lines 312 and electrical vias 313. The electrical metal lines 312 and electrical vias 313 are electrically connected to S/D regions 204b or gate stacks 208 of the transistor devices 205. The electrical metal lines 312 extends lengthwise horizontally in various metal layers, and the electrical vias 313 are vertically disposed between the electrical metal lines 312. The electrical vias 313 are columns or pillars that connect electrical metal lines 312 between the various metal layers. In an embodiment, a first electrical metal line 312 extends lengthwise along the x direction and lands on one or more device-level metal features 212 (e.g., S/D vias or gate vias). A first electrical via 313 lands on the first electrical metal line 312 as a vertical interconnect to route the first electrical metal 312 to a second electrical metal line 312. The second electrical metal line 312 lands on the first electrical via 313 and may extend lengthwise along the y direction. Additional electrical vias 313 and metal lines 312 may be similarly disposed over the second electrical metal line 312. In any case, the electrical metal lines 312 extend beyond side surfaces of the electrical vias 313 along the x or y direction.

Still referring to FIG. 2A, the frontside interconnect structure 300 further includes thermal vias 112 electrically isolated from the S/D regions 204b and gate stacks 208 of the transistor devices 205. The thermal vias 112 are for heat dissipation and do not route any actual circuit signals from the transistor devices 205. The thermal vias 112, the electrical metal lines 312, and the electrical vias 313 are each embedded in a frontside IMD layer 302. The frontside IMD layer 302 may be multi-layered, each layer embeds a metal layer in the frontside interconnect structure 300. As shown, the thermal vias 112 are isolated from the electrical metal lines 312 and the electrical vias 313 by the frontside IMD layer 302. Each of the thermal vias 112 has a greater height in the vertical z direction than each of the electrical metal lines 312 and electrical vias 313. The thermal vias 112 are vertical columns without lateral extensions beyond its vertical side surfaces, and the thermal vias 112 penetrate through more than a metal layer of the frontside interconnect structure 300. In other words, the thermal vias 112 may extend and penetrate through more than one layer of the frontside interconnect structure 300 (e.g., through multiple metal line layers) while the electrical vias 313 only extend through one layer to connect between electrical metal lines 312 of different metal line layers. As such, each of the thermal vias 112 spans a greater vertical height than at least a height of an electrical via plus a height of an electrical metal line 312 in the vertical direction. In the present embodiment, the thermal vias 112 penetrate and span an entire vertical height of the frontside IMD layer 302.

Still referring to FIG. 2A, the thermal vias 112 only include floating thermal vias 112a. Floating thermal vias 112a refers to thermal vias 112 that are not only electrically isolated but also physically isolated from the electrical metal lines 312 and the electrical vias 313. That is, no portion of the floating thermal vias 112a are in direct contact with the electrical metal lines 312 and the electrical vias 313. In an embodiment, the floating thermal vias 112a are completely surrounded by and directly contacting dielectric materials (e.g., contacting the frontside IMD layer 302 on side surfaces, the ILD layer 211 on bottom surfaces, and an oxide bonding layer 500 on top surfaces). In the present embodiment, each of the floating thermal vias 112a include copper.

Still referring to FIG. 2A, the backside interconnect structure 400 includes backside electrical metal lines 412 and backside electrical vias 413. The backside electrical metal lines 412 and backside electrical vias 413 are electrically connected to S/D regions 204b or gate stacks 208 of the transistor devices 205. The backside electrical metal lines 412 extends lengthwise horizontally in various metal layers, and the backside electrical vias 413 are vertically disposed between the backside electrical metal lines 412. The backside electrical vias 413 are columns or pillars that connect backside electrical metal lines 412 between the various backside metal layers. In an embodiment, a first backside electrical metal line 412 extends lengthwise along the x direction and lands on one or more buried rails 214 or backside vias (not shown) from a back side of the device substrate 202. A first backside electrical via 413 lands on the first backside electrical metal line 412 as a vertical interconnect to route the first backside electrical metal line 412 to a second backside electrical metal line 412. The second backside electrical metal line 412 lands on the first backside electrical via 413 and may extend lengthwise along the y direction. Additional backside electrical vias 413 and backside electrical metal lines 412 may be similarly disposed over the second backside electrical metal line 412. In any case, the backside electrical metal lines 412 extend beyond side surfaces of the backside electrical vias 413 along the x or y direction. In some embodiments, like as shown, there may be one or more feedthrough vias 216 that penetrate through the entire device layer 200 to interconnect between an electrical metal line 312 in the frontside interconnect structure 300 and a backside electrical metal line 412 in the backside interconnect structure 400.

Still referring to FIG. 2A, the backside interconnect structure 400 further includes thermal vias 112 electrically isolated from the S/D regions 204b and gate stacks 208 of the transistor devices 205. The thermal vias 112, the backside electrical metal lines 412, and the backside electrical vias 413 are each embedded in a backside IMD layer 402. The backside IMD layer 402 may be multi-layered, each layer embeds a metal layer in the backside interconnect structure 400. As shown, the thermal vias 112 are isolated from the backside electrical metal lines 412 and the backside electrical vias 413 by the backside IMD layer 402. Similar to the thermal vias 112 in the frontside interconnect structure 300, each of the thermal vias 112 in the backside interconnect structure 400 have a greater height in the vertical z direction than each of the backside electrical metal lines 412 and backside electrical vias 413. These thermal vias 112 are vertical columns without lateral extensions beyond its vertical side surfaces, and they penetrate through more than a metal layer of the backside interconnect structure 400. In other words, the thermal vias 112 in the backside interconnect structure may extend and penetrate through more than one layer of the backside interconnect structure 400 (e.g., through multiple metal line layers) while the backside electrical vias 413 only extends through one layer to connect between backside electrical metal lines 412 of different metal line layers. As such, each of the thermal vias 112 spans a greater vertical height than at least a height of a backside electrical via 413 plus a height of a backside electrical metal line 412 in the vertical direction. In the present embodiment, the thermal vias 112 in the backside interconnect structure 400 penetrate and span an entire vertical height of the backside IMD layer 402.

Still referring to FIG. 2A, the thermal vias 112 in the backside interconnect structure 400 only include floating thermal vias 112a. The floating thermal vias 112a have been previously described and will not be described again for the sake of brevity. In an embodiment, the floating thermal vias 112a in the backside interconnect structure 400 are completely surrounded by and directly contacting dielectric materials.

FIG. 2B illustrates a cross-sectional view of an IC structure 100 having thermal vias 112, and particularly non-floating thermal vias 112b, according to an embodiment of the present disclosure. The IC structure 100 in FIG. 2B is similar to the IC structure 100 in FIG. 2A, and the similar features will not be described again for the sake of brevity. The difference is that in addition to floating thermal vias 112a, FIG. 2B additionally illustrates multiple non-floating thermal vias 112b. Non-floating thermal vias 112b refers to thermal vias 112 in which at least one end of the non-floating thermal vias 112b is in direct contact and landing on a metal line in the frontside and/or backside interconnect structures 300 and 400 (e.g., landing on an electrical metal line 312 or a backside electrical metal line 412). The another end may not be in contact with any metal layer. Since the non-floating thermal vias 112b land on metal lines in the frontside and/or backside interconnect structure 300 and 400, they may have a smaller vertical height than the floating thermal vias 112a. For each of the non-floating thermal vias 112b, there is a metal portion and a thermal insulating portion. The thermal insulating portion is at the end where there is direct contact with a metal line in the frontside and/or backside interconnect structure 300 and 400, and the metal portion is at the end where there is no direct contact with any metal line in the frontside and/or backside interconnect structure 300 and 400. In an embodiment, the thermal insulating portion includes about 1 nm to 50 nm of an insulating material with high electrical resistivity and high thermal conductivity (such as diamond nanoparticles, AlN, c-BN, Al₂O₃, or BeO). The electrical resistivity p of the insulating material should be greater than 10⁸ Ωm for isolating electrical signals (e.g., between 10¹⁰ Ωm and 10¹⁶ Ωm). The thermal conductivity k for the insulating material should be between about 10 and 500 W/m/K for absorbing heat dissipation. The thermal insulating portion separates a metal layer electrically connected to the transistor devices 205 from the metal portion. The metal portion includes similar materials as the floating thermal vias 112a (e.g., copper). The thermal insulating portion is included because the metal portion of the non-floating thermal vias 112b should not be electrically connected to the electrical metal lines 312 or the backside electrical metal lines 412. Otherwise, there would be unintended signal routing. In other words, the insulating material is needed to isolate the metal portions. Note that in a further embodiment, both ends of a non-floating thermal vias 112b may contact a metal line and thus both ends include the insulating portion while the middle portion is the metal portion.

FIG. 3A illustrates a cross-sectional view of an IC structure 100 having floating thermal vias 112a and a heat spreader layer 600, according to an embodiment of the present disclosure. FIG. 3A is similar to FIG. 2A, and the similar features will not be described again for the sake of brevity. The difference is that in addition to floating thermal vias 112a, FIG. 3A additionally illustrates a heat spreader layer 600 between the backside interconnect structure 400 and the AP layer 602. In this configuration, backside electrical metal lines 412 can connect to aluminum bonding pads in the AP layer 602 through one or more through vias 613. In this way, electrical signals can still be passed through the heat spreader layer 600. The heat spreader layer 600 may be a layer with electrical and thermal via holes which allow metal/signal lines to pass through. Note however that although electrical via holes are required to route circuit signals, thermal via holes through the heat spreader layer 600 may be optional. This is because the heat spreader layer 600 may already have high thermal conductivity, and so the thermal vias do not have to go through the heat spreader layer 600 and can simply be connected to it.

As shown, a top surface of the heat spreader layer 600 may be in direct contact with a bottom surface of the floating thermal vias 112a, backside electrical metal lines 412, and/or backside electrical vias 413. In an embodiment, the floating thermal vias 112a may land on the heat spreader layer 600 without penetrating through it. The IC structure 100 further includes through vias 613 that penetrate through the heat spreader layer 600 to route backside electrical metal lines 412 to aluminum bonding pads in the AP layer 602. In an embodiment (as shown), there may also be one or more floating thermal vias 112a that penetrate through the heat spreader layer 600 such that the heat spreader layer 600 surrounds the floating thermal vias 112a. Note that the floating thermal vias 112a are isolated from the through vias 613 by the electrically isolating material of the heat spreader layer 600 (e.g., diamond). In an embodiment, one or more floating thermal vias 112a may span an entire vertical height of the backside interconnect structure 400 plus the entire vertical height of the heat spreader layer 600. These floating thermal vias 112a may land on a top surface of the AP layer 602 (e.g., passivation layer) but do not land on metal features in the AP layer (e.g., aluminum bonding pads and/or redistribution routing lines).

FIG. 3B illustrates a cross-sectional view of an IC structure 100 having floating thermal vias 112a and a heat spreader layer 600, according to another embodiment of the present disclosure. FIG. 3B is similar to FIG. 3A, and the similar features will not be described again for the sake of brevity. The difference is that the heat spreader layer 600 is disposed between the AP layer 602 and the C4 layer 604. In this case, the AP layer 602 is disposed on a back side of the backside interconnect structure 400, the heat spreader layer 600 is disposed on a back side of the AP layer 602, and the C4 layer 604 is disposed on a back side of the heat spreader layer 600. In this configuration, aluminum bonding pads in the AP layer 602 can connect to C4 bumps in the C4 layer 604 through one or more through vias 613. In this way, electrical signals can still be passed through the heat spreader layer 600. The heat spreader layer 600 may be a layer with electrical and thermal via holes which allow metal/signal lines to pass through. Note however that although electrical via holes are required to route circuit signals, thermal via holes through the heat spreader layer 600 and/or the AP layer 602 may be optional. This is because the heat spreader layer 600 and/or the AP layer 602 may already have high thermal conductivity, and so the thermal vias do not have to go through these layers but can simply be connected to them.

As shown, a top surface of the heat spreader layer 600 may be in direct contact with aluminum bonding pads in the AP layer 602, which are then electrically routed to the backside electrical metal lines 412. The top surface of the heat spreader layer 600 may also be in direct contact with a bottom surface of one or more floating thermal vias 112a. The IC structure 100 includes through vias 613 that penetrate through the heat spreader layer 600 to route aluminum bonding pads in the AP layer 602 to the interconnect bumps in the C4 layer 604. In an embodiment, one or more of the floating thermal vias 112a may land on the AP layer 602 without penetrating through it to land on the heat spreader layer 600. In an embodiment, one or more of the floating thermal vias 112a may penetrate through the AP layer 602 to land on the heat spreader layer 600. In an embodiment, one or more of the floating thermal vias 112a may further penetrate through the heat spreader layer 600 to land on the C4 layer 604. Note that the floating thermal vias 112a that penetrate through the heat spreader layer 600 are isolated from the through vias 613 by the electrically isolating material of the heat spreader layer 600 (e.g., diamond). In an embodiment, the floating thermal vias 112a may span an entire vertical height of the backside interconnect structure 400 plus the entire vertical height of the AP layer 602 plus the entire vertical height of the heat spreader layer 600. These floating thermal vias 112a land on a top surface of the C4 layer 604 but do not land on metal features in the C4 layer (e.g., interconnect bumps).

FIG. 4A illustrates a cross-sectional view of an IC structure 100 having floating and non-floating thermal vias 112a and 112b and a heat spreader layer 600, according to an embodiment of the present disclosure. FIG. 4A is similar to FIG. 3A and the similar features will not be described again for the sake of brevity. The difference is that FIG. 4A further includes non-floating thermal vias 112b as described and illustrated in FIG. 2B. In the embodiment shown in FIG. 4A, the IC structure 100 may further include one or more non-floating thermal vias 112b that penetrate through the heat spreader layer 600 as shown. These non-floating thermal vias 112b may be directly below the backside electrical metal lines 412 and have insulating portions that directly land on the backside electrical metal lines 412.

FIG. 4B illustrates a cross-sectional view of an IC structure 100 having floating and non-floating thermal vias 112a and 112b and a heat spreader layer 600, according to another embodiment of the present disclosure. FIG. 4B is similar to FIG. 4A and the similar features will not be described again for the sake of brevity. The difference is that the heat spreader layer 600 in FIG. 4B is disposed between the AP layer 602 and the C4 layer 604, which is described and illustrated in FIG. 3B. As shown, the non-floating thermal vias 112b that penetrate through the heat spreader layer 600 may have a greater vertical height than the non-floating thermal vias 112b in the frontside and backside interconnect structures 300 and 400.

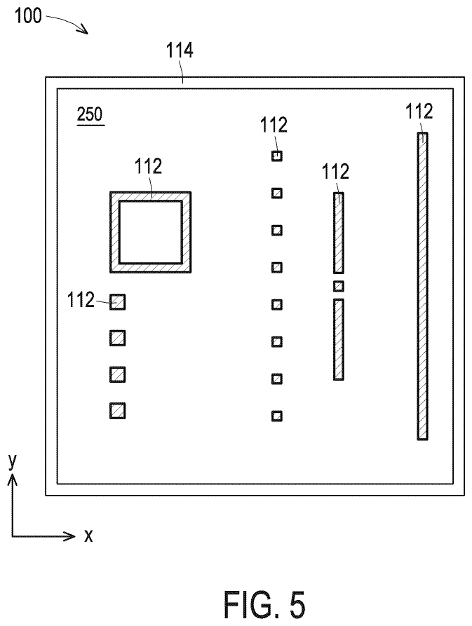

FIG. 5 illustrates a top view of an IC chip (or an IC structure 100) having a circuit region 250. The circuit region 250 is where the different IC features described above are formed. The IC chip may further include one or more seal rings 114 outside and surrounding the circuit region 250. The seal rings 114 protect the circuit region 250 from damage caused by the sawing of the IC chips, and they may be formed by outer edge interconnected metal lines and vias.

Still referring to FIG. 5, inside the circuit region 250, thermal vias 112 of different shapes and configurations may be formed. In one embodiment, the thermal vias 112 may have similar dimensions as the electrical and backside electrical vias 313 and 413 in the x and/or y direction. This promotes structure uniformity and easier process integration. In another embodiment, the thermal vias 112 may have greater dimensions compared to the electrical and backside electrical vias 313 and 413 in the x and/or y direction. In an embodiment, the electrical and backside electrical vias 313 and 413 have widths in the x and/or y direction between about 10 nm to about 3 m, and the thermal vias have widths in the x and/or y direction between about 100 nm to about 10 m. Greater dimensions promote better heat dissipation, and since the thermal vias 112 do not actually route signal or power lines, they can be positioned further away from the signal and power routes to avoid shorts, thus having more space for greater dimensions. In an embodiment, the distance between the thermal vias 112 and the electrical and backside electrical vias 313 and 413 ranges between about 50 nm to about 500 nm. In an embodiment, the thermal vias 112 may be e.g., square vias having equal dimensions in the x and y direction. In another embodiment, the thermal vias 112 may be e.g., rectangular slot vias having unequal dimensions in the x and y direction, e.g., one side extends longer lengthwise in the x or y direction. In another embodiment, the thermal vias 112 may be e.g., ring vias that encircle a particular area in the circuit region 250. Note that the present disclosure contemplates any combinations of square vias, rectangular slot vias, and ring vias, and the different shaped vias may have side surfaces aligned along the y or x direction.

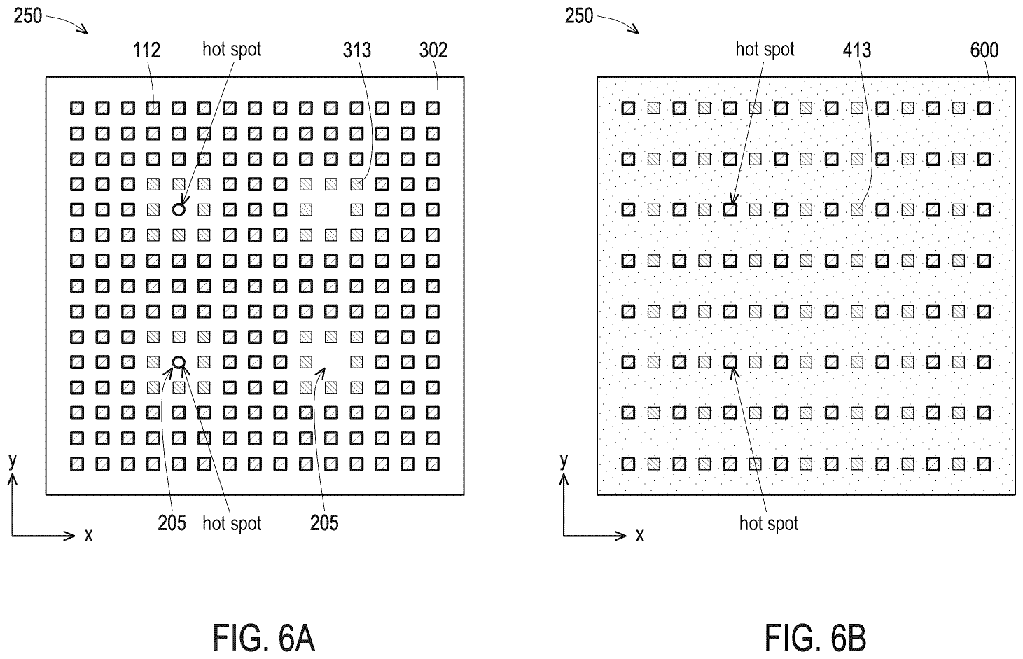

FIGS. 6A, 6B, 7A, 7B, 8A, and 8B illustrate top view portions of the circuit region 250 in FIG. 5, according to various embodiments. FIGS. 6A, 7A, and 8A illustrate top views of thermal vias 112 and electrical vias 313 cut along an x-y plane in the frontside interconnect structure 300. FIGS. 6B, 7B, and 8B illustrate top views of thermal vias 112 and backside electrical vias 413 cut along an x-y plane in the heat spreader layer 600. FIGS. 6A, 7A, and 8A corresponds to FIGS. 6B, 7B, and 8B, respectively, except that the location of the top view cut is different. Note that the same via configuration in FIGS. 6B, 7B, and 8B may equally apply to a top view cut along an x-y plane in the backside interconnect structure 400 (not shown). In each of FIG. 6A-8A, the IC chip (or IC structure 100) include areas of electrical vias 313 surrounding transistor devices 205. Some of these transistor devices 205 may be high power devices (e.g., memory transistor devices requiring high read/write speed) and some of the transistor devices 205 may be low power devices (e.g., logic devices for simple switching functions). The high power devices may generate hot spots where heat is concentrated.

Referring now to FIGS. 6A-6B, the thermal vias 112 may be uniformly distributed along the x-y plane without regard to the location of hot spots. As shown, the thermal vias 112 are uniformly distributed and adjacent to the electrical vias 313 in the frontside interconnect structure 300. And the thermal vias 112 in the heat spreader layer 600 (or backside interconnect structure 400) are also uniformly distributed and adjacent to the backside electrical vias 413.

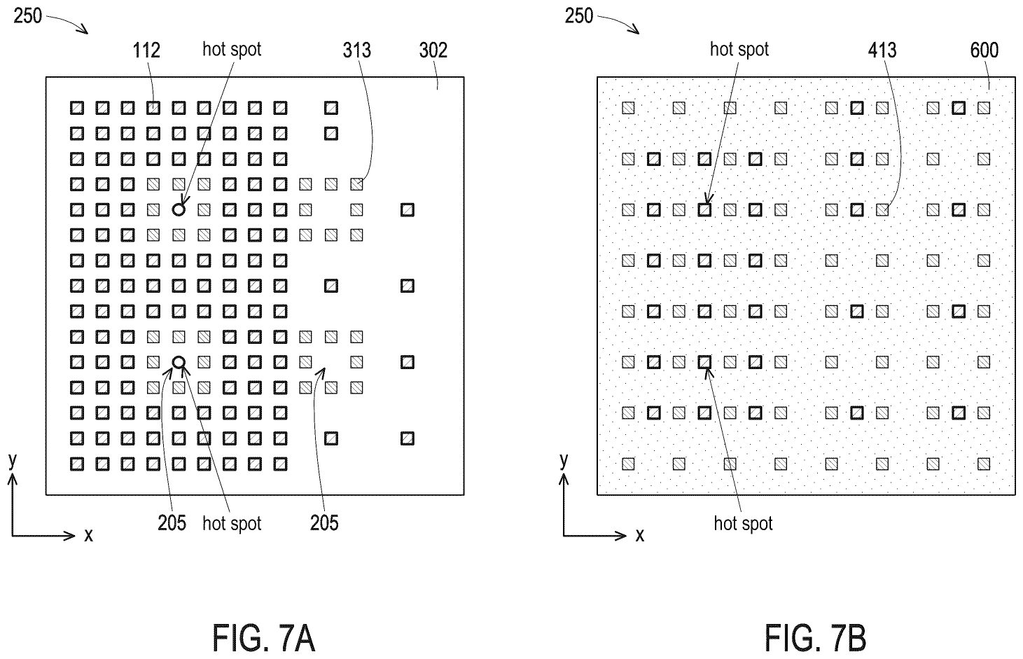

Referring to FIGS. 7A-7B, the thermal vias 112 may be non-uniformly distributed along the x-y plane. In this embodiment, the thermal vias 112 are more concentrated in hot spot areas (e.g., around high power devices). In this way, more space may be conserved for signal routing in non-hot spot areas. In other words, the thermal vias 112 may be localized to the high power devices to reduce area requirement.

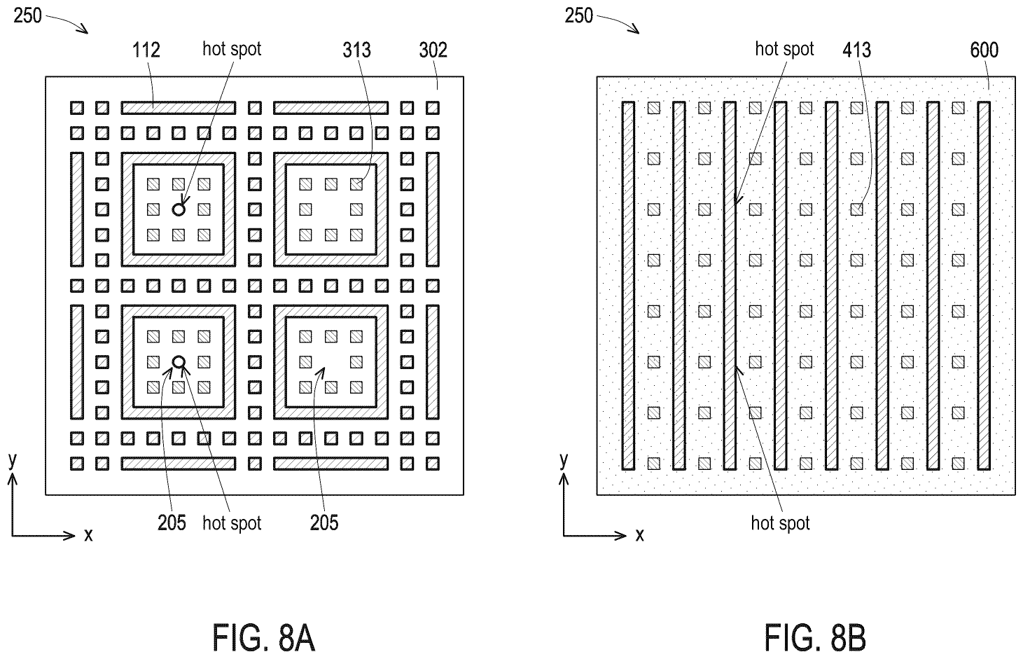

Referring to FIGS. 8A-8B, the thermal vias 112 may have different shapes, such as a ring shape, an elongated bar shape, etc., much like those described in FIG. 5. As shown, the thermal vias 112 may elongate along the x or y direction, and they may also be ring shaped with continuous or non-continuous contact. These elongated thermal vias 112 further improves thermal absorption.

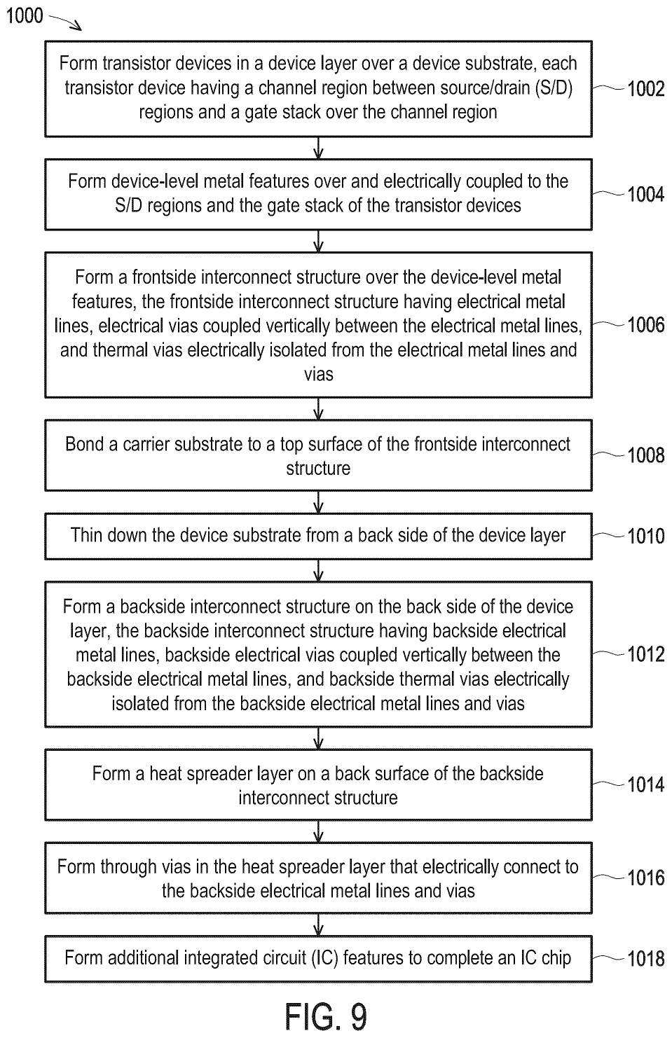

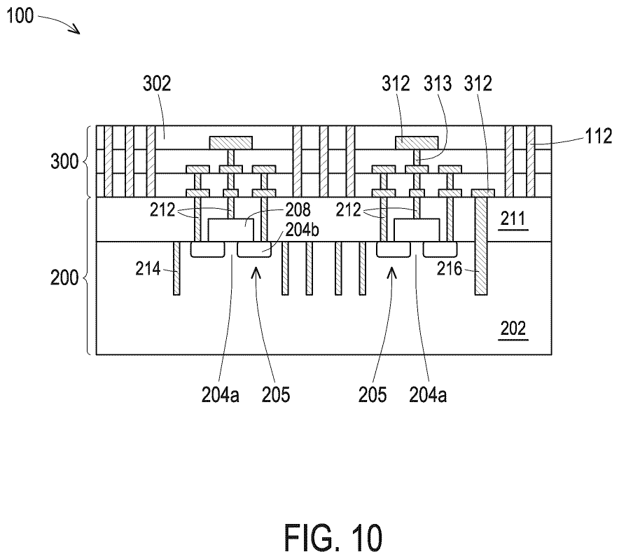

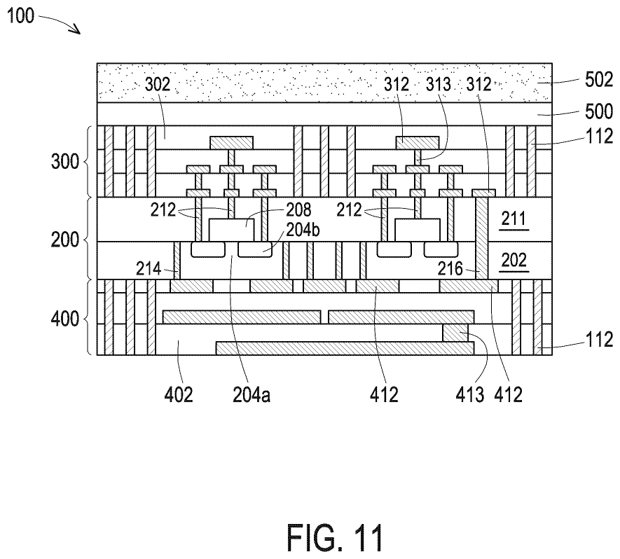

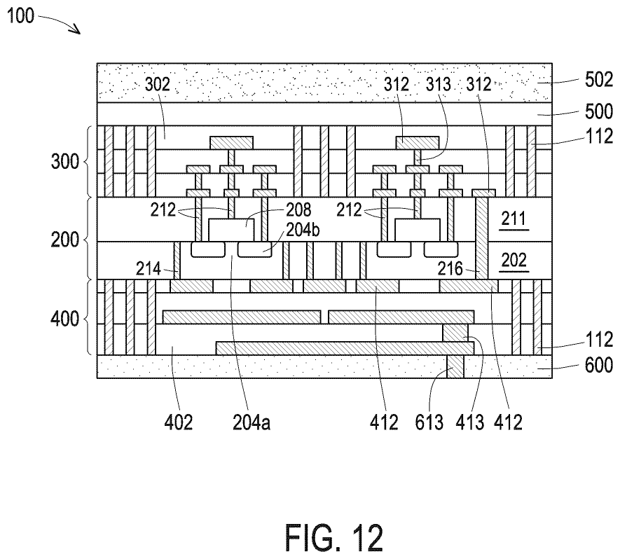

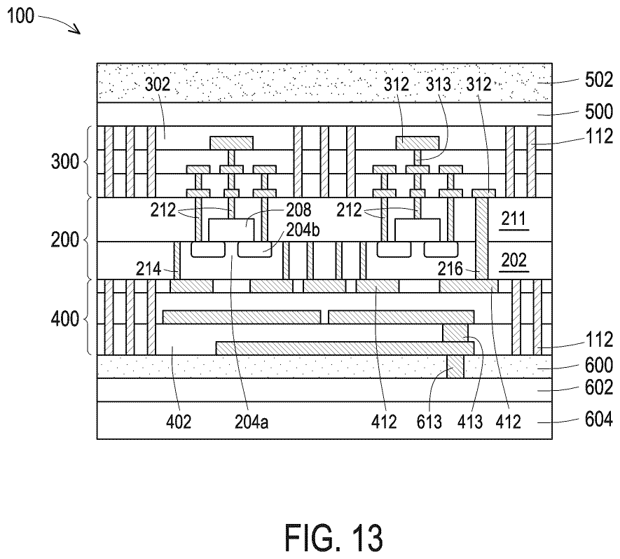

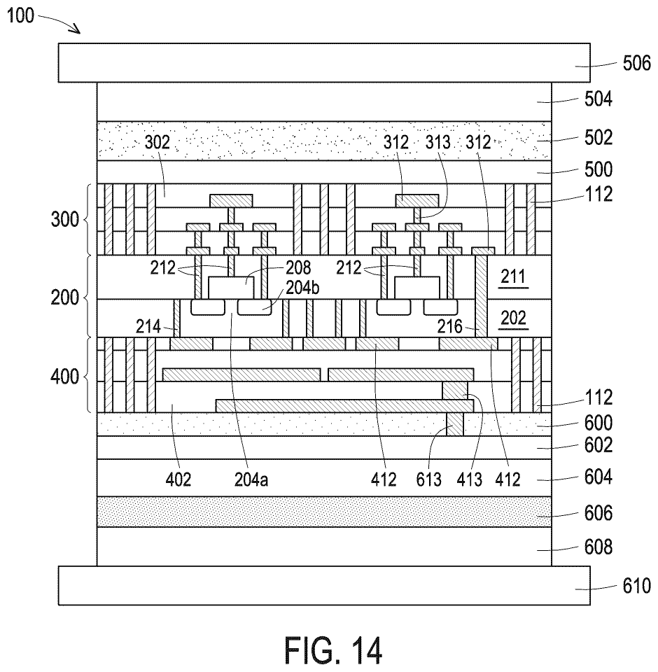

FIG. 9 illustrates a flow chart of a method 1000 to form an IC structure 100 having thermal vias 112 and a heat spreader layer 600, according to an embodiment of the present disclosure. FIGS. 10-14 illustrate forming an IC structure 100 at intermediate stages of fabrication, processed in accordance with the method 1000 of FIG. 9. FIGS. 10-14 may illustrate features previously described, and some of these features will not be described again for the sake of brevity. At a high level, the method 1000 includes: (1) FEOL processing to form transistor devices 205, device-level metal features 212, and buried rails 214, then forming a frontside interconnect structure 300 having electrical metal lines 312, electrical vias 313, and thermal vias 112 as described herein (see FIG. 10); (2) bonding the IC workpiece to a silicon carrier substrate 502 (see FIG. 11); (3) thinning down the device substrate 202 in the device layer 200 and forming a backside interconnect structure 400 having backside electrical metal lines 412, backside electrical vias 413, and thermal vias 112 as described herein (see FIG. 11); (4) performing CMP on a back surface of the backside interconnect structure 400 to reduce surface roughness then deposit a heat spreader layer 600 (see FIG. 12); (5) making via connection through the heat spreader layer 600 and depositing an AP layer 602 and C4 layer 604 (see FIGS. 12-13); and (6) complete processing of the IC structure 100 with deposition of a TIM layer 504, a top lid 506, a package substrate 606, a BGA structure 608, and a PCB 610 (see FIG. 14).

Referring now to FIG. 10, the method 1000 at operation 1002 forms transistor devices 205 in a device layer 200. The transistor devices 205 may be formed over or within a device substrate 202 in the device layer 200. Each transistor device 205 includes a channel region 204a between source/drain (S/D) regions 204b and a gate stack 208 over the channel region 204a. The transistor devices 205 may be formed by any suitable deposition and patterning techniques.

Each of the S/D regions 204b may include epitaxial S/D features doped with n-type dopants and/or p-type dopants that sandwich transistor channels in the channel regions 204a. In some embodiments, for n-type transistors, the S/D regions 204b include epitaxial S/D features having silicon doped with carbon, phosphorous, arsenic, other n-type dopant, or combinations thereof (for example, forming Si:C epitaxial source/drain features, Si:P epitaxial source/drain features, or Si:C:P epitaxial source/drain features). In some embodiments, for p-type transistors, the S/D regions 204b include epitaxial S/D features having silicon germanium or germanium doped with boron, other p-type dopant, or combinations thereof (for example, forming Si:Ge:B epitaxial source/drain features). In some embodiments, portions of the epitaxial features closer to the transistor channels in the channel regions 204a have lower doping concentrations than portions of the epitaxial features laterally away from the transistor channels.

Each of the gate stacks 208 includes a gate electrode over a gate dielectric (not shown), and the gate dielectric is disposed on the channel region 204a. In some embodiments, an interfacial layer (e.g., a silicon oxide layer) is disposed vertically between the channel region 204a and the gate dielectric. The gate dielectric layer includes a high-k dielectric material, such as materials having a dielectric constant greater than silicon oxide (k≈3.9). The gate dielectric layer may include HfO, LaO, ZrO, AlO, TiO, or TaO. The gate electrode includes a suitable conductive material, such as Al, W, Co, TiAl, TiN, or other metal gate materials. For gate-all-around FETs, the gate dielectric layer and the gate electrode may each wrap around multiple transistor channels in a channel region 204a. Each transistor devices 205 may further include spacer features such as gate spacers and inner spacers for gate-all-around FETs. The gate spacers may line sidewalls of the gate stack 208 above the topmost channels, and the inner spacers may be vertically disposed between transistor channels and laterally disposed between the gate stacks 208 and the S/D regions 204b. The gate spacers and the inner spacers may include silicon oxide, silicon nitride, silicon oxycarbide, silicon oxycarbonitride, silicon carbonitride, metal nitride, or a suitable dielectric material.

Still referring to FIG. 10, the method 1000 at operation 1004 forms device-level metal features 212 over and electrically coupled to the S/D regions 204b and/or the gate stack 208 of the transistor devices. As described previously, these features may be formed in an ILD layer 211 over the device substrate 202. As part of operation 1004, the method 1000 may form buried rails 214 that is buried in the device substrate 202 and extending below the transistor devices 205. Further, as part of operation 1004, the method 1000 may form feedthrough vias 216 that extend and penetrate through the ILD layer 211 and partially through the device substrate 202. In some embodiments, a bottom surface of the buried rails 214 and a bottom surface of the feedthrough vias 216 are substantially coplanar. The device-level metal features 212, the buried rails 214, and the feedthrough vias 216 may be formed through standard FEOL processing techniques. The FEOL processing may include depositing one or more ILD sublayers, performing one more patterning processes that include lithography and etching to form patterned trenches in the ILD sublayers, performing one or more deposition processes such as CVD, PVD, or ALD to form metal features in the patterned trenches, and performing one or more planarization processes such as CMP after depositing the metal features. Note that metals such as Ru, W, or Mo may be used as the metal features instead of Cu for the device-level metal features 212, the buried rails 214, and the feedthrough vias 216. This is to withstand high temperatures (e.g., greater than 900 degrees Celsius) during FEOL processing and to prevent electromigration.

Still referring to FIG. 10, the method 1000 at operation 1006 forms a frontside interconnect structure 300 over the device-level metal features 212. The frontside interconnect structure 300 includes electrical metal lines 312, electrical vias 313 coupled vertically between the electrical metal lines 312, and thermal vias 112 electrically isolated from the electrical metal lines 312 and vias 313. These features are formed in a frontside IMD layer 302.

In an embodiment, the thermal vias 112 are formed after forming the electrical metal lines 312 and electrical vias 313. In this way, the thermal vias 112 are formed by etching through the entirety (or multiple sublayers) of the frontside IMD layer 302 in a single etching process, thereby forming deep trenches, then depositing a metal (e.g., Cu) into the deep trenches. In another embodiment, the thermal vias 112 are formed in lockstep with the forming of the electrical metal lines 312 and electrical vias 313. In this way, the thermal vias 112 are formed in multiple etching and depositing steps, and they are formed at the same time as when the different electrical metal lines 312 and vias 313 are formed in IMD sublayers of the frontside IMD layer 302.

Note that the thermal vias 112 may be formed as floating thermal vias 112a or non-floating thermal vias 112b. When forming floating thermal vias 112a, patterned trenches are first formed, then a metal (e.g., Cu) is deposited into the patterned trenches. Note that the patterned trenches may penetrate through multiple IMD sublayers of the frontside IMD layer 302. In a first embodiment, the patterned trenches may be formed laterally adjacent to where the transistor devices 205 are formed. In a second embodiment, the patterned trenches may be formed directly above where the transistor devices 205 are formed (like the non-floating thermal vias 112b), however, in this case, the patterned trenches should only partially penetrate the frontside IMD layer 302 without exposing any of the electrical metal lines 312 and vias 313. When forming non-floating thermal vias 112b, patterned trenches are first formed to expose a top surface of an electrical metal line 312, then an insulating thermal via material (e.g., diamond nanoparticles, AlN, c-BN, Al₂O₃, or BeO) is deposited, then a metal (e.g., Cu) is deposited over the insulating thermal via material. Forming the thermal vias 112 is compatible with BEOL processes. As such, the metals (e.g., Cu) deposited to form the thermal vias 112 may be deposited by PVD at low temperatures (less than 400 degrees Celsius) as opposed to high temperatures (e.g., greater than 900 degrees Celsius) during FEOL processing.

Referring now to FIG. 11, the method 1000 at operation 1008 bonds a carrier substrate 502 (e.g., silicon substrate) to a top surface of the frontside interconnect structure 300. Operation 1008 may include depositing a bonding layer 500 over the frontside interconnect structure 300, then depositing the carrier substrate 502 over the bonding layer 500. The bonding layer glues the carrier substrate 502 to the rest of the IC workpiece.

Still referring to FIG. 11, the method 1000 at operation 1010 thins down the device substrate 202 from a back side of the device layer 200. Operation 1010 may be performed before or after the bonded IC structure 100 is flipped for further backside processing. Operation 1010 thins down the exposed backside of the device substrate 202 by a suitable process such as a mechanical grinding process and/or a chemical thinning process. In the embodiment shown, the operation 1014 may also thin down backside portions of the buried rails 214 and feedthrough vias 216 such that bottom surfaces of the buried rails 214 and feedthrough vias 216 are coplanar with a bottom surface of the device substrate 202. Where the device substrate 202 is partially removed, portions of the remaining device substrate 202 still embed portions of the transistor devices 205. Where the device substrate 202 is substantially or fully removed, the thinning down exposes portions of the transistor devices 205 (e.g., S/D regions 204b). In either case, due to the device substrate 202 partially or fully removed, the device substrate 202 is no longer able to or no longer efficient in absorbing heat caused by device self-heating. As such, the thermal vias 112 and/or heat spreader layer 600 supplements or replaces the heat absorbing function of the device substrate 202.

Still referring to FIG. 11, the method 1000 at operation 1012 forms a backside interconnect structure 400 on the back side of the device layer 200. The backside interconnect structure 400 includes backside electrical metal lines 412, backside electrical vias 413 coupled vertically between the backside electrical metal lines 412, and thermal vias 112 electrically isolated from the backside electrical metal lines 412 and vias 413. These features are formed in a backside IMD layer 402, which may include multiple sublayers. In the embodiment shown, the backside electrical metal lines 412 are formed to directly contact the buried rails 214 and the feedthrough vias 216. The thermal vias 112 formed in the backside interconnect structure 400 may be formed similar to those formed in the frontside interconnect structure 300.

Referring now to FIG. 12, the method 1000 at operation 1014 forms a heat spreader layer 600 on a back surface of the backside interconnect structure 400 by any suitable deposition process. In an embodiment, a planarization process such as CMP is performed on the back surface of the backside interconnect structure 400 before depositing the heat spreader layer 600. The planarization process may reduce the surface roughness of the backside interconnect structure 400 to less than 1 nm. Note that in embodiments where the heat spreader layer 600 is formed between the AP layer 602 and the C4 layer 604, the AP layer 602 is deposited on the back surface of the backside interconnect structure 400, and the heat spreader layer 600 is deposited on the back surface of the AP layer 602.

Still referring to FIG. 12, the method 1000 at operation 1016 forms through vias 613 in the heat spreader layer 600 that electrically connect to the backside electrical metal lines 412 and vias 413. As shown, the through vias 613 may directly land on a backside electrical metal line 412. Note that in embodiments where the heat spreader layer 600 is formed between the AP layer 602 and the C4 layer 604, the through vias 613 may directly land on an aluminum bonding pad in the AP layer 602.

Referring now to FIG. 14, the method 1000 at operation 1018 forms additional integrated circuit (IC) features to complete an IC chip. These include the TIM layer 504, the top lid 506, the package substrate 606, the BGA structure 608, and the PCB 610 previously described.

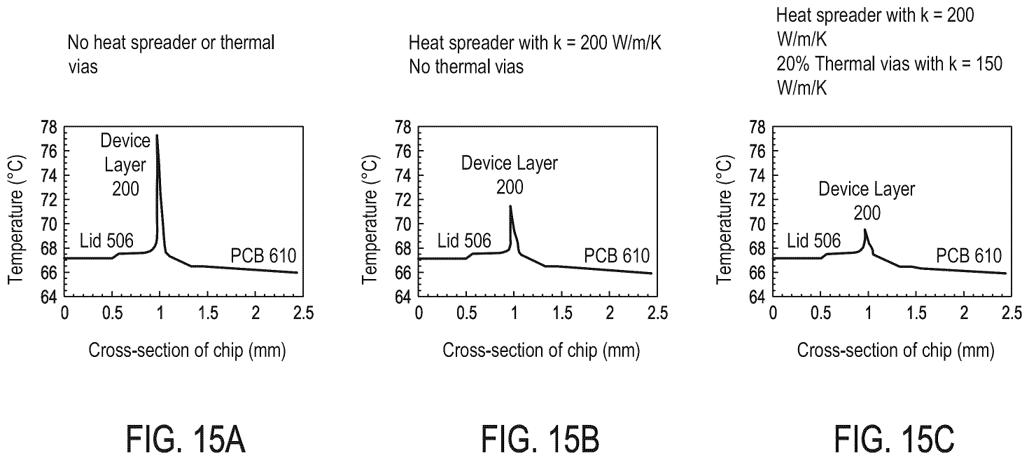

For illustration purposes, FIGS. 15A-15C illustrate thermal improvements that can be achieved through heat spreaders and thermal vias. The specific values for temperature, cross-section distance, and thermal conductivity k are not intended to be limiting. Other values (or ranges of values) are equally possible to demonstrate the thermal improvement of the heat spreaders and thermal vias.

FIG. 15A shows the temperature profile through the cross-section of the IC structure 100 in FIG. 1 from top to bottom (e.g., from the lid 506 to the PCB 610) and with a 750 W/cm² hotspot (50 μm) in the device layer 200. FIG. 15A illustrates an instance where there is no heat spreader layer 600 and no thermal vias 112. As shown, the maximum temperature (Tmax) is ˜77° C. FIG. 15B shows the temperature profile for the same IC structure 100 in FIG. 1, but with a heat spreader layer 600 having k=200 W/m/K and still no thermal vias 112. As shown, the maximum temperature (Tmax) is ˜71° C. FIG. 15C shows the temperature profile for the same IC structure 100 in FIG. 1 with a heat spreader layer 600 having k=200 W/m/K and 20% of the frontside and backside interconnect structures 300 and 400 replaced with thermal vias with k=150 W/m/K. As shown, the maximum temperature (Tmax) is ˜69° C. Note that a higher thermal conductivity heat spreader layer 600 (e.g. with k=500 W/m/K) can also be used to further reduce the hotspot temperature.

Although not limiting, the present disclosure offers advantages for IC semiconductor structures with backside power delivery. One example advantage is incorporating thermal vias in the frontside and/or backside interconnect structure. Another example advantage is incorporating a heat spreader layer on a backside of the backside interconnect structure. Another example advantage is incorporating thermal vias with insulating portions landing on metal lines.

One aspect of the present disclosure pertains to an integrated circuit (IC) structure. The IC structure includes a device layer having transistor devices, the transistor devices having channel regions between source/drain (S/D) regions and gate stacks over the channel regions; a frontside interconnect structure on a front side of the device layer, wherein the frontside interconnect structure includes first metal features and second metal features embedded in an intermetal dielectric (IMD) layer, the first and second metal features are isolated from each other by the IMD layer, the first metal features are electrically connected to an S/D region or a gate stack of the transistor devices, and the second metal features are electrically isolated from the transistor devices; a backside interconnect structure on a back side of the device layer. The backside interconnect structure includes third metal features and fourth metal features embedded in a backside IMD layer, the third and fourth metal features are isolated from each other by the backside IMD layer, the third metal features are electrically connected to an S/D region or a gate stack of the transistor devices, and the fourth metal features are electrically isolated from the transistor devices. The IC structure further includes a heat spreader layer on a back side of the backside interconnect structure. The heat spreader layer is made of a heat spreader material that is thermally conductive and electrically insulating.

In an embodiment, the first and the third metal features include electrical metal lines and electrical vias, and the electrical vias are vertically disposed between the electrical metal lines. The second and the fourth metal features include thermal vias, and each of the thermal vias have a greater height in a vertical direction than each of the electrical vias.

In a further embodiment, the electrical metal lines extend beyond a side surface of the electrical vias along a first direction or along a second direction perpendicular to the first direction, and the thermal vias are metal pillars having vertical side surfaces without extensions beyond the vertical side surfaces.

In an embodiment, the second and the fourth metal features are first thermal vias completely surrounded by and directly contacting dielectric materials, and the IC structure further includes: second thermal vias embedded in the IMD layer, where each of the second thermal vias includes a metal portion and a thermal insulating portion, the thermal insulating portions of the second thermal vias directly land on the first metal features, and the thermal insulating portions of the second thermal vias separate the first metal features from the metal portions of the second thermal vias; and third thermal vias embedded in the backside IMD layer, where each of the third thermal vias includes a metal portion and a thermal insulating portion, the thermal insulating portions of the third thermal vias directly land on the third metal features, and the thermal insulating portions of the third thermal vias separate the third metal features from the metal portions of the third thermal vias.

In a further embodiment, the metal portion of the second and the third thermal vias include copper, and the thermal insulating portion of the second and the third thermal vias include diamond, AlN, BN, Al₂O₃, BeO, or a combination thereof.

In an embodiment, the fourth metal features span from the device layer to the heat spreader layer and the fourth metal features land on a top surface of the heat spreader layer.

In an embodiment, the IC structure further includes a redistribution layer (RDL) structure on a back side of the heat spreader layer, the RDL structure includes aluminum pads embedded in a passivation layer. The heat spreader layer embeds a through via that electrically connects the third metal features to the aluminum pads.

In an embodiment, the heat spreader material has a thermal conductivity between about 10 and about 500 W/m/K.

In an embodiment, the heat spreader material includes diamond, AlN, BN, Al₂O₃, BeO, or a combination thereof.

In an embodiment, the transistor devices include high power devices and low power devices, and the second and the fourth metal features are concentrated laterally closer to the high power devices than the low power devices.

Another aspect of the present disclosure pertains to an integrated circuit (IC) structure. The IC structure includes a device layer having transistor devices, the transistor devices having channel regions between source/drain (S/D) regions and gate stacks over the channel regions; a frontside interconnect structure on a front side of the device layer, where the frontside interconnect structure includes first metal features and second metal features embedded in an intermetal dielectric (IMD) layer, the first and second metal features are isolated from each other by the IMD layer, the first metal features are electrically connected to an S/D region or a gate stack of the transistor devices, and the second metal features are electrically isolated from the transistor devices; a bonding oxide layer over the frontside interconnect structure; and a substrate over the bonding oxide layer.

In an embodiment, the first metal features include electrical metal lines and electrical vias, and the electrical vias are vertically disposed between the electrical metal lines, where the second metal features include thermal vias, and each of the thermal vias have a greater height in a vertical direction than at least a height of an electrical via plus a height of an electrical metal line.

In an embodiment, the second metal features are floating thermal vias completely surrounded by and directly contacting dielectric materials, and the IC structure further includes: non-floating thermal vias embedded in the IMD layer, where each of the non-floating thermal vias includes a metal portion and a thermal insulating portion, the thermal insulating portion directly lands on the first metal features, and the thermal insulating portion separates the first metal features from the metal portion.

In a further embodiment, the metal portion has a greater height in a vertical direction than the thermal insulating portion. In a further embodiment, the floating thermal vias have a greater height in a vertical direction than the non-floating thermal vias.

In an embodiment, the IC structure further includes a backside interconnect structure on a back side of the device layer, where the backside interconnect structure includes third metal features and fourth metal features embedded in a backside IMD layer, the third and fourth metal features are isolated from each other by the backside IMD layer, the third metal features are electrically connected to an S/D region or a gate stack of the transistor devices, and the fourth metal features are electrically isolated from the transistor devices; and a heat spreader layer on a back side of the backside interconnect structure, where the heat spreader layer is made of a heat spreader material that is thermally conductive and electrically insulating, where the fourth metal features directly contacts the heat spreader layer.

Another aspect of the present disclosure pertains to a method of forming an integrated circuit (IC). The method includes forming transistor devices in a device layer over a device substrate, each transistor device having a channel region between source/drain (S/D) regions and a gate stack over the channel region; forming device-level contacts over and electrically coupled to the S/D regions and the gate stack of the transistor devices; forming a frontside interconnect structure over the device-level contacts, the frontside interconnect structure having electrical metal lines, electrical vias coupled vertically between the electrical metal lines, and thermal vias electrically isolated from the electrical metal lines and vias; bonding a substrate to a top surface of the frontside interconnect structure; thinning down the device substrate from a back side of the device layer; forming a backside interconnect structure on the back side of the device layer, the backside interconnect structure having backside electrical metal lines, backside electrical vias coupled vertically between the backside electrical metal lines, and backside thermal vias electrically isolated from the backside electrical metal lines and vias; and forming a heat spreader layer on a back surface of the backside interconnect structure, where the heat spreader layer is made of a heat spreader material that is thermally conductive and electrically insulating.

In an embodiment, the method further includes forming a redistribution layer (RDL) structure on a back surface of the heat spreader layer, wherein the RDL structure includes aluminum bonding pads embedded in a passivation layer.

In a further embodiment, forming the heat spreader layer further comprises forming through vias in the heat spreader layer, the through vias electrically couple the backside electrical metal lines to the aluminum bonding pads.

In an embodiment, the thermal vias, the backside thermal vias, and the heat spreader layer are formed by physical vapor deposition or chemical vapor deposition at a temperature less than 400 degrees Celsius.

The details of the method and device of the present disclosure are described in the attached drawings. The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) structure, comprising:
a device layer having transistor devices, the transistor devices having channel regions between source/drain (S/D) regions and gate stacks over the channel regions;
a frontside interconnect structure on a front side of the device layer, wherein the frontside interconnect structure include first metal features embedded in an intermetal dielectric (IMD) layer, the first metal features electrically connected to an S/D region or a gate stack of the transistor devices;
a backside interconnect structure on a back side of the device layer, wherein the backside interconnect structure includes second metal features and third metal features embedded in a backside IMD layer, the second and third metal features isolated from each other by the backside IMD layer, wherein the second metal features are electrically connected to an S/D region or a gate stack of the transistor devices, and the third metal features are electrically isolated from the transistor devices; and
a heat spreader layer on a back side of the backside interconnect structure, wherein the heat spreader layer is made of a heat spreader material that is thermally conductive and electrically insulating.

2. The IC structure of claim 1,
wherein the first and the second metal features include electrical metal lines and electrical vias, and the electrical vias are vertically disposed between the electrical metal lines,
wherein the third metal features include thermal vias, and each of the thermal vias have a greater height in a vertical direction than each of the electrical vias.

3. The IC structure of claim 2,
wherein the electrical metal lines extend beyond a side surface of the electrical vias along a first direction or along a second direction perpendicular to the first direction, and the thermal vias are metal pillars having vertical side surfaces without extensions beyond the vertical side surfaces.

4. The IC structure of claim 1,
wherein the first and the second metal features include electrical metal lines and electrical vias, and the electrical vias are vertically disposed between the electrical metal lines,
wherein the third metal features include thermal vias, and each of the thermal vias have a greater width in a lateral direction than each of the electrical vias.

5. The IC structure of claim 1,
wherein the third metal features are first thermal vias completely surrounded by and directly contacting dielectric materials, further comprising:
second thermal vias embedded in the backside IMD layer, wherein each of the second thermal vias includes a metal portion and a thermal insulating portion, the thermal insulating portions directly land on one of the second metal features, and the thermal insulating portions separate the second metal features from the metal portions.

6. The IC structure of claim 5, wherein the metal portion includes copper, and the thermal insulating portion includes diamond, AlN, BN, Al2O3, BeO, or a combination thereof.

7. The IC structure of claim 1, wherein the third metal features span from the device layer to the heat spreader layer and the third metal features land on a top surface of the heat spreader layer.

8. The IC structure of claim 1, wherein the third metal features span at least an entire height of the backside interconnect structure.

9. The IC structure of claim 1, wherein the heat spreader material has a thermal conductivity between about 10 and about 500 W/m/K.

10. The IC structure of claim 1, wherein the heat spreader material includes diamond, AlN, BN, Al2O3, BeO, or a combination thereof.

11. An integrated circuit (IC) structure, comprising:
a device layer having transistor devices, the transistor devices having channel regions between source/drain (S/D) regions and gate stacks over the channel regions; and
a backside interconnect structure on a back side of the device layer and under the channel regions, wherein the backside interconnect structure includes first metal features and second metal features embedded in a backside intermetal dielectric (IMD) layer, the first and second metal features are isolated from each other by the IMD layer, the first metal features are electrically connected to an S/D region or a gate stack of the transistor devices, and the second metal features are electrically isolated from the transistor devices,
wherein the first metal features include electrical metal lines and electrical vias, and the electrical vias are vertically disposed between the electrical metal lines,
wherein the second metal features include thermal vias, and each of the thermal vias have a greater height in a vertical direction than at least a height of an electrical via plus a height of an electrical metal line.

12. The IC structure of claim 11, wherein the thermal vias are floating thermal vias completely surrounded by and directly contacting dielectric materials.

13. The IC structure of claim 11, wherein the thermal vias are non-floating thermal vias embedded in the IMD layer, wherein each of the non-floating thermal vias includes a metal portion and a thermal insulating portion, the thermal insulating portion directly lands on the first metal features, and the thermal insulating portion separates the first metal features from the metal portion.

14. The IC structure of claim 13, wherein the metal portion has a greater height in a vertical direction than the thermal insulating portion.

15. The IC structure of claim 11, further comprising:
a heat spreader layer on a back side of the backside interconnect structure, wherein the heat spreader layer is made of a heat spreader material that is thermally conductive and electrically insulating, wherein the second metal features physically interfaces with the heat spreader layer,
wherein the heat spreader material includes diamond, AlN, BN, Al2O3, BeO, or a combination thereof.

16. The IC structure of claim 11, further comprising:
a frontside interconnect structure on a front side of the device layer, wherein the frontside interconnect structure includes third metal features and fourth metal features embedded in a frontside IMD layer, the third and fourth metal features are isolated from each other by the frontside IMD layer, the third metal features are electrically connected to an S/D region or a gate stack of the transistor devices, and the fourth metal features are electrically isolated from the transistor devices.

17. A method of forming an integrated circuit (IC) structure, comprising:
forming transistor devices in a device layer over a device substrate, each transistor device having a channel region between source/drain (S/D) regions and a gate stack over the channel region;
forming device-level contacts over and electrically coupled to the S/D regions and the gate stack of the transistor devices;
forming a frontside interconnect structure over the device-level contacts, the frontside interconnect structure having electrical metal lines and electrical vias coupled vertically between the electrical metal lines, wherein the electrical metal lines and electrical vias are electrically coupled to an S/D region or a gate stack of the transistor devices;
bonding a substrate to a top surface of the frontside interconnect structure;
thinning down the device substrate from a back side of the device layer; and
forming a backside interconnect structure on the back side of the device layer, the backside interconnect structure having backside electrical metal lines, backside electrical vias coupled vertically between the backside electrical metal lines, and backside thermal vias electrically isolated from the backside electrical metal lines and vias, wherein the backside electrical metal lines and backside electrical vias are electrically coupled to an S/D region or a gate stack of the transistor devices, and the backside thermal vias are electrically insulated from all of the S/D regions and gate stacks.

18. The method of claim 17, wherein the backside thermal vias are formed by physical vapor deposition or chemical vapor deposition at a temperature less than 400 degrees Celsius.

19. The method of claim 17, further comprising:
forming a heat spreader layer on a back surface of the backside interconnect structure, wherein the heat spreader layer is made of a heat spreader material that is thermally conductive and electrically insulating.

20. The method of claim 19, further comprising:
forming a redistribution layer (RDL) structure on a back surface of the heat spreader layer, wherein the RDL structure includes aluminum bonding pads embedded in a passivation layer.
